(19) United States
(12) Patent Application Publication
(10) Pub. No.: US 2019/0100948 A1
(43) Pub. Date: Apr. 4, 2019

(54) METHOD FOR PRODUCING A HANDLE APPARATUS, AND CORRESPONDING HANDLE APPARATUS

(71) Applicants: Matthias Low, Ratingen (DE); Artur Boczek, Wuppertal (DE); Frank Herrmann, Essen (DE)

(72) Inventors: Matthias Low, Ratingen (DE); Artur Boczek, Wuppertal (DE); Frank Herrmann, Essen (DE)

(73) Assignee: Huf Huelsbeck & Fuerst GmbH & Co. KG, Velbert (DE)

(21) Appl. No.: 16/136,352

(22) Filed: Sep. 20, 2018

(30) Foreign Application Priority Data
Oct. 4, 2017 (DE) 10 2017 123 015.7

(51) Int. Cl. E05B 85/16; H05K 5/00; H05K 5/02; H05K 5/06

(52) U.S. Cl. CPC E05B 85/16; H05K 5/064; H05K 5/023; H05K 5/0052

(57) ABSTRACT

A method for producing a handle apparatus includes providing an elongate handle base body which has a central receiving space in which electronic components are arranged, applying a sealing joint around the central receiving space and attaching a handle cover to the elongate handle base body. When the handle cover is attached, the sealing joint is compressed so that the central receiving space is sealed via the sealing joint. An inlet opening and an outlet opening are formed on opposite ends of the central receiving space. The handle apparatus is oriented vertically and filled with a liquid sealing compound via the inlet opening, wherein gases which are present in the central receiving space are discharged via the outlet opening. A corresponding handle apparatus is also disclosed.

### BACKGROUND

The present invention relates to a method for producing a handle apparatus, and to a corresponding handle apparatus.

Handle apparatuses in which electronic components are arranged in an internal receiving space are known from the prior art. To protect these electronic components from influences of weather, these electronic components are arranged, for example, in an enclosure made of a sealing compound, wherein this enclosure is arranged in the receiving space during the production of the handle apparatus. A method for producing a handle apparatus is known from the prior art, in which the electronic components are arranged in the receiving space, the same is encapsulated with a sealing compound, and the handle apparatus is then assembled.

A disadvantage of the aforementioned method is that a relatively long amount of time is required to produce a handle apparatus, since the handle apparatus can only be assembled after the sealing compound has cured.

It is therefore an object of the present invention to provide a method according to which handle apparatuses with encapsulated electronic components can be produced quickly. It is a further object of the present invention to provide a corresponding handle apparatus.

### BRIEF SUMMARY

The present object is addressed according to the invention by a method according to claim 1. According to the invention, an elongate handle base body is configured with a central receiving space, electronics components arranged on a carrier are arranged in the central receiving space, a sealing joint is made on the elongate handle base body around the central receiving space, enclosing the same, and a suitable handle cover is attached to the elongate handle base body.

When the handle cover is attached, the sealing joint is compressed in such a manner that the central receiving space is sealed from the exterior via the sealing joint, wherein an inlet opening and an outlet opening are formed on opposite ends of the central receiving space. The central receiving space is thus sealed via the sealing joint in such a manner that a fluid communication with a medium outside the receiving space is possible only via the inlet opening and the outlet opening. The receiving space is bounded and/or closed off by attaching the handle cover. As such, the receiving space before the attachment of the handle cover does not completely correspond to the same after the attachment. Throughout the present application, the term “receiving space” is used for the open and closed space.

The handle apparatus assembled from the handle base body and the handle cover is then oriented vertically so that the inlet opening is arranged at the bottom—and a liquid sealing compound which fills the central receiving space from bottom to top is introduced via the inlet opening, wherein gases present in the central receiving space are discharged through the outlet opening during the filling with the liquid sealing compound. After the filling with the sealing compound, the same is allowed to cure, wherein the handle apparatus preferably remains oriented vertically for this purpose, at least at the beginning of the curing phase.

The method according to the invention enables an accelerated production of the handle apparatus, since—due to the provision of the sealing joint—it can be filled with liquid sealing compound from the bottom immediately after the assembly of the handle base body and the handle cover. The sealing joint prevents leakage of the liquid sealing compound and enables the removal of the handle apparatus filled with sealing compound from the workstation used for this purpose immediately after the filling with sealing compound, and the filling of another handle apparatus which is not yet filled with liquid sealing compound. Thus, according to the invention, it is not necessary to wait for the curing of the liquid sealing compound to complete the production of the exterior of the handle apparatus.

The precise sealing compound which is used depends on the specific case. It must be fillable in the liquid state and then cure. The exact composition depends on the materials used in the handle base body and the handle cover. Furthermore, the weight and the cost of the sealing compound can play a role in the selection of the sealing compound used. For a person skilled in the art, the selection of a sealing compound suitable for the application is a common practice.

According to the invention, the inlet opening and the outlet opening are formed on opposite ends of the handle base body, enabling fluid communication of the central receiving space with the surroundings. How the inlet opening and the outlet opening are formed is immaterial to the invention. What is essential is that the receiving space is sealed from the outside via the sealing joint, and a fluid communication with the surroundings is possible via the inlet and the outlet opening. For example, the inlet and outlet openings may be formed upon the assembly of the handle cover and the handle base body. Thus, it is conceivable that both the handle base body and the handle cover have two—for example, semicircular—recesses which form the inlet opening and the outlet opening upon being assembled. Alternatively, it is conceivable that the inlet opening and the outlet opening are created in the handle base body and/or the handle cover immediately after the assembly of the handle apparatus, for example by a bore hole.

The abovementioned possibilities for introducing the inlet opening and the outlet opening are theoretically conceivable. However, in practice, such approaches should not be particularly relevant. In a practical, preferred embodiment which is structurally particularly simple, the elongate handle base body is provided with two openings which form the inlet opening and the outlet opening when the handle cover is attached. During the attachment of the handle cover, the openings do not change as such. However, they obtain their function as the inlet opening and the outlet opening only upon the assembly of the handle cover and the handle base body when the sealing joint is present. This is because, before the assembly of the handle base body and the handle cover, there is no receiving space which is closed except for the openings.

By using a corresponding sealing compound, it is possible according to the invention to completely fill the receiving space, which is closed except for the openings, with sealing compound. For technical reasons, the sealing compound always contacts the inlet opening. With precise dosing of the liquid sealing compound, it is possible to fill the cavity so that the liquid sealing compound does not escape through the outlet opening, and rather reaches to just below the outlet (the receiving space is filled from bottom to top with liquid sealing compound). In a preferred embodiment, the inlet opening and/or the outlet opening is/are provided with a cover after the curing of the liquid sealing compound. Depending on how precisely the outlet opening is formed, the use of a cover at the outlet opening may be omitted. Due to the process control, however, it may be desirable for haptic and optical reasons to provide in particular the inlet opening with the aforementioned cover.

In a preferred embodiment, in order to shield the electronic components inside the handle apparatus from disturbing electronic influences from the outside, a protective cover is arranged over the electronic components before the application of the handle cover, said protective cover in the finished handle apparatus being oriented toward the outside and shielding the electronic components from the outside.

The material from which the sealing joint is formed is not essential to the present invention. Rather, it is essential that the central receiving space in the interior of the handle apparatus (with the exception of the inlet opening and the outlet opening) is sealed in such a way via the sealing joint that the liquid sealing compound can be filled in from below. For example, it is conceivable that the sealing joint is provided with a sealing compound based on polyurethane. Such sealing compounds have a number of advantages: they have only one component, are elastic, low in odor, non-corrosive, demonstrate a wide adhesive spectrum, and are also solvent-free. With a chemical adaptation of the sealing compound based on polyurethane, the same can also be adapted to the specific application—for example, to the materials used for the handle base body and the handle cover.

The present invention further relates to a handle apparatus for a motor vehicle, having an elongate handle base body and a handle cover, wherein a sealing joint which, together with the handle base body and the handle cover, defines a central, enclosed receiving space, is arranged between the handle base body and handle cover, wherein electronics components arranged on a carrier, as well as the sealing compound, are arranged in the central receiving space, and wherein the receiving space has an inlet opening and an outlet opening on opposite ends, wherein the same can be filled at least in sections with sealing compound. The sealing compound protects the electronic components in the receiving space from environmental influences and also helps to fix them in the handle apparatus and/or the receiving space. The handle apparatus according to the invention can be produced, for example, by the abovementioned method.

In a preferred embodiment of the handle apparatus according to the invention, the handle base body comprises the inlet opening and/or the outlet opening. This preferred embodiment can be produced most quickly, with the fewest steps, according to the method described above. If, for example, one were to provide the inlet and/or outlet opening in the handle cover, further work steps may be necessary after filling the handle apparatus with sealing compound to hide the openings from a user.

The method described above, which can be used for producing the handle apparatus, by way of example, requires that at least the inlet opening is filled with sealing compound after completion of the handle apparatus. Due to haptic and/or optical considerations, in a preferred embodiment, the inlet and/or outlet opening is/are provided with a cover.

In order to electronically shield the electronic components arranged in the receiving space, in a preferred embodiment, a protective cover is arranged in the sealed, central receiving space over the carrier with the electronic components.

In a preferred embodiment which facilitates the positioning and fixing of the sealing joint prior to assembly of the handle base body and the handle cover, a plurality of recesses into which the sealing joint extends are arranged on the circumference of the handle base body.

### BRIEF DESCRIPTION OF THE DRAWINGS

Below, a preferred embodiment of the method according to the invention, and a preferred embodiment of the handle apparatus according to the invention, will be described with reference to the drawings, in which:

FIGS. 1a and 1b show oblique views of an embodiment of the handle apparatus according to the invention,

FIGS. 2-6 show different oblique views of the handle base body without the handle cover attached, at different method steps,

FIG. 7 shows a side view of the handle apparatus before filling with liquid sealing compound, and

FIG. 8 shows a sectional view of the handle apparatus during filling with liquid sealing compound.

### DETAILED DESCRIPTION

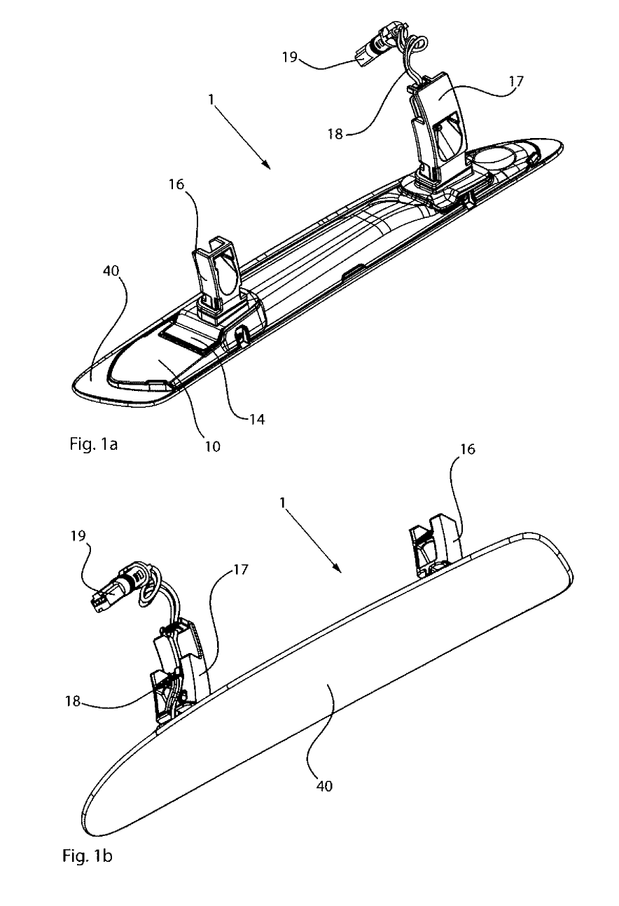

FIGS. 1a and 1b show oblique views of a preferred embodiment of the handle apparatus 1 according to the invention. In the preferred embodiment, the handle apparatus comprises a handle base body 10 and a handle cover 40, with the handle cover 40 attached to the handle base body 10. FIG. 1b shows the handle cover 40 from the outside—that is, as it faces a user—wherein the exact configuration of the handle cover in terms of its appearance and/or shape depends on the specific application. For example, one application is the installation of the handle apparatus in doors of a motor vehicle; and in such a case, the shape and/or color of the surface of the handle cover will depend on the color and design of the motor vehicle.

In FIG. 1a, the back of the handle apparatus is shown, with two fastening means 16, 17 with which the handle apparatus is fixed, for example, on or in a door of a motor vehicle. According to the exact configuration of the handle apparatus, it can be fixed in the door of the motor vehicle via the fastening means 16, 17 in such a way that the handle apparatus is pivotable—that is, it can be pivoted upwards in a classic manner for the user. In alternative embodiments, it can only be grasped from behind, and for this purpose a corresponding recess is provided in the door of the motor vehicle. Lines 18 are guided out of the right fastening means, at the end of which a plug 19 is arranged via which the handle apparatus can be connected to a central control device of the motor vehicle, by way of example.

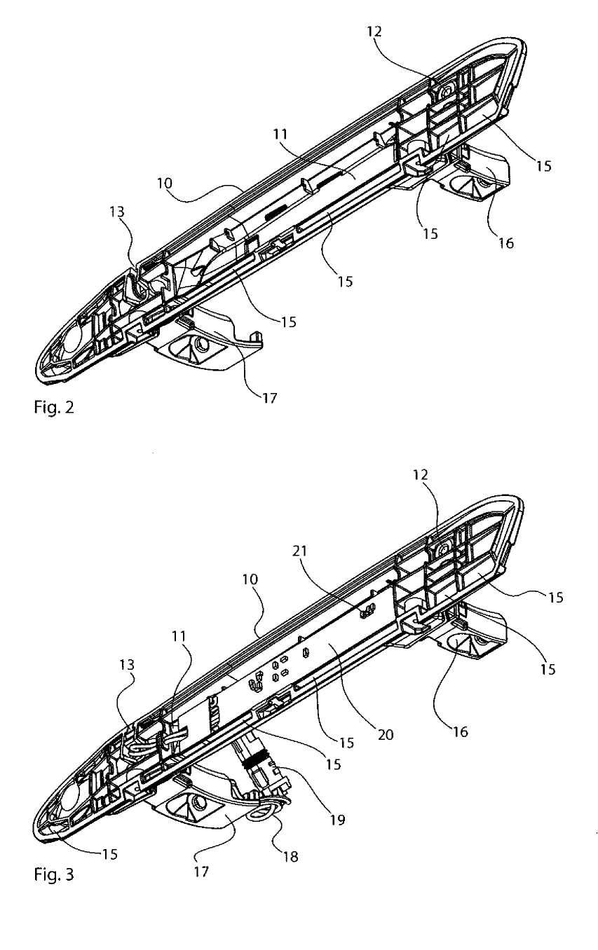

FIG. 2 shows an oblique view of the handle base body, wherein a central receiving space 11 is formed in the central region of the handle base body. In the right section of the housing of the handle base body, an inlet opening 12 is provided, via which a sealing compound can be introduced later into the handle apparatus. In the “left” side of FIG. 2, an outlet opening 13 can be seen, which is also provided in the embodiment shown to guide lines out of the interior of the handle apparatus (the corresponding lines were shown in FIGS. 1a and 1b). FIG. 2 shows the first method step of a preferred embodiment of the method according to the invention, namely that a handle base body 10 is provided.

FIG. 3 shows a further oblique view of the handle base body, wherein a carrier 20 with a plurality of electronic components 21 is arranged in the receiving space 11. The carrier is connected via lines 18 to a plug 19. The lines 18 are guided out of the handle base body at an outlet opening 13, wherein the outlet opening is not completely closed off by the lines being guided out. FIG. 3 shows the situation after the second method step, after the carrier 20 with the electronic components has been arranged in the receiving space 11.

In FIGS. 2 and 3, several recesses 15 can be seen on the circumference of the handle base body. These recesses serve, as described in the following figures, to receive and fix the sealing joint.

FIG. 4 shows the handle base body with an applied sealing joint 30 which extends around the circumference of the handle base body 10. In the embodiment shown, the sealing joint does not extend along the entire outer circumference of the handle base body. Some places are left clear. At these locations, there may be latching with the handle cover. These locations can also be covered by the sealing joint in an alternative embodiment. Regardless of whether these “clearances” are present, a receiving space which is sealed except for the openings is formed upon the attachment of the handle cover.

After the sealing joint is applied to the handle base body, the handle cover 40 is attached to the handle base body. After the attachment of the handle cover, the exterior of the handle apparatus is finished. Upon the attachment of the handle cover, the sealing joint between the handle base body and the handle cover is compressed, and the central receiving space 11 in which the carrier with the plurality of electronic components 21 is arranged, is sealed via the sealing joint from the outside. In other words, when the handle base body 10 and the handle cover 40 are assembled, a sort of cavity is formed by means of the sealing joint which, due to the provision of the inlet and outlet openings 12, 13 in the handle base body, is in fluid communication with the surroundings. The two joined pieces—the handle base body and the handle cover—are connected to each other via the sealing joint. At the same time, the sealing compound ensures that the interior is sealed from the outside in such a way that a fluid communication with the surroundings is only possible via the inlet and the outlet opening. In the preferred embodiment described here, a protective cover 22 is also inserted in the receiving space 11 before the handle base body and the handle cover are assembled, protecting the electronic components inside the subsequent handle apparatus from external electronic influences. In FIG. 5, the protective cover 22 is shown shortly before it is applied to the carrier 20 with the electronic components 21.

FIG. 6 shows the finished handle apparatus filled with sealing compound, wherein the handle cover has been omitted to illustrate the interior of the handle apparatus. On the outer circumference of the handle base body, it can be seen that the sealing joint is compressed, and the recesses 15 recognizable in FIGS. 2 and 3 can be recognized here as well due to the compression. However, this does not mean that no sealing joint is arranged between the individual recesses 15. Rather, the sealing joint is, or can be, thinner in these regions. It can be seen that sealing compound 50 extends from the inlet opening, which is concealed in FIG. 6 by sealing compound 50, until shortly before the outlet opening 13. That is, the interior of the handle apparatus is substantially completely filled with sealing compound. The amount of sealing compound required depends on the exact configuration of the handle apparatus and the components arranged in the interior of the handle apparatus.

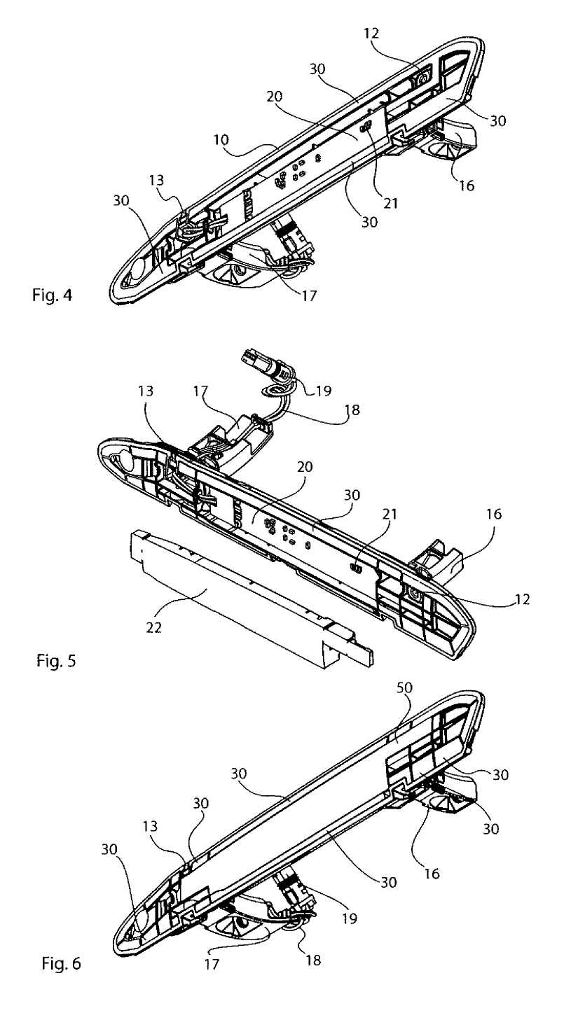

In FIG. 7, the handle apparatus according to the invention is shown oriented vertically, wherein the inlet opening 12 is arranged in the lower section. In FIG. 7, a sealing compound line 60 which is coupled to the inlet opening 12 for introducing liquid sealing compound is schematically indicated.

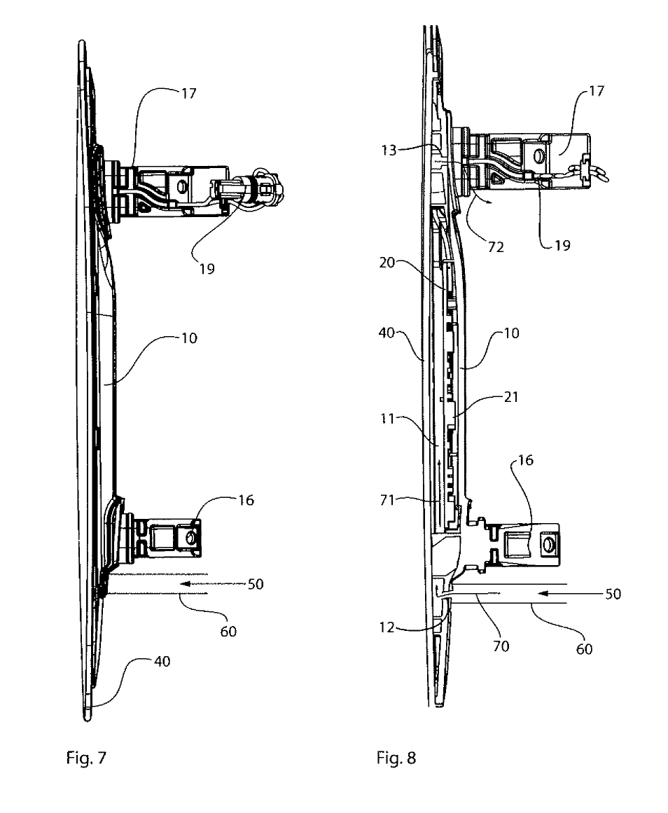

FIG. 8 shows a sectional view of the vertically oriented handle apparatus. FIG. 8 is intended to illustrate that the handle apparatus according to the invention is filled from below with liquid sealing compound 50. The same enters into the handle apparatus from below via the inlet device 12, as indicated by the arrow 70. As the filling of liquid sealing compound progresses, the level of the sealing compound within the handle apparatus continues to rise, as illustrated by the arrow 71. During the filling of the liquid sealing compound, the gas in the handle apparatus exits via the outlet opening 13, which is arranged in the upper region of the handle apparatus, as illustrated via the arrow 72. The gas which escapes from the handle apparatus depends on the specific atmosphere in which the manufacture of the handle apparatus is carried out.

As soon as the handle apparatus is sufficiently provided with liquid sealing compound, the supply of the same is halted and the sealing compound supply 60 is removed. If, at this time, the sealing compound in the inlet opening 12 has not yet cured, a closure of the inlet opening 12 must accompany the removal of the sealing compound supply 60. Alternatively, the handle apparatus can be stored horizontally with a corresponding arrangement of the inlet and outlet opening until the sealing compound has cured.

After the curing of the sealing compound, the inlet opening and the outlet opening can be equipped with a cover to haptically and visually hide them. In order to prevent sealing compound from escaping from the outlet opening 13, only as much sealing compound as is needed to make a complete seal of the electronic components and a fixation of the same inside the handle apparatus is filled into the same.

1. A method for producing a handle apparatus for a motor vehicle, comprising
providing an elongate handle base body with a central receiving space,
arranging electronic components disposed on a carrier in the central receiving space,
applying a sealing joint to the elongate handle base body around the central receiving space,
attaching a suitable handle cover to the elongate handle base body,
wherein, when the handle cover is attached, the sealing joint is compressed in such a manner that the central receiving space is sealed from the outside via the sealing joint, and an inlet opening and an outlet opening are formed on opposite ends of the central receiving space,
wherein the handle apparatus is oriented vertically, such that the inlet opening is arranged at the bottom,
a liquid sealing compound is filled in via the inlet opening, and fills the central receiving space from bottom to top,
during the filling with the sealing compound gases present in the central receiving space are discharged via the outlet opening.

2. The method for producing a handle apparatus for a motor vehicle according to claim 1, wherein the elongate handle base body is provided with two openings, which, when the handle cover is attached, form the inlet opening and the outlet opening.

3. The method for producing a handle apparatus for a motor vehicle according to claim 1, wherein the inlet opening and/or the outlet opening is/are equipped with a cover after a curing of the sealing compound.

4. The method for producing a handle apparatus for a motor vehicle according to claim 1, wherein, prior to the attachment of the handle cover, a protective cover is arranged over the electronic components.

5. A handle apparatus for a motor vehicle, comprising
an elongate handle base body and a handle cover, wherein a sealing joint, which together with the handle base body and the handle cover defines a central enclosed receiving space, is arranged between the handle base body and handle cover,
wherein electronic components arranged on a carrier, as well as a sealing compound, are disposed in the receiving space, and wherein the receiving space includes an inlet opening and an outlet opening located on opposite ends, which can be filled at least in sections with the sealing compound.

6. The handle apparatus for a motor vehicle according to claim 5, wherein the handle base body comprises the inlet opening and/or the outlet opening.

7. The handle apparatus for a motor vehicle according to claim 5, wherein the inlet opening and/or the outlet opening is/are provided with a cover.

8. The handle apparatus for a motor vehicle according to claim 5, wherein a protective cover is arranged in the sealed receiving space over the carrier with electronic components.

9. The handle apparatus for a motor vehicle according to claim 5, wherein the handle base body has a plurality of recesses on its circumference, into which recesses the sealing joint extends.
